(19) United States
(12) Patent Application Publication
(10) Pub. No.: US 2017/0256746 A1
(43) Pub. Date: Sep. 7, 2017

(54) LIGHT EXTRACTION SUBSTRATE FOR ORGANIC LIGHT-EMITTING DIODE, MANUFACTURING METHOD THEREFOR, AND ORGANIC LIGHT-EMITTING DIODE INCLUDING SAME

(71) Applicant: Corning Precision Materials Co., Ltd., Chungcheongnam-do (KR)

(72) Inventor: Kwang Je Woo, Chungcheongnam-do (KR)

(73) Assignee: Corning Precision Materials Co., Ltd., Chungcheongnam-do (KR)

(21) Appl. No.: 15/510,493

(22) PCT Filed: Sep. 7, 2015
(86) PCT No.: PCT/KR2015/009399

§ 371 Date: Mar. 10, 2017

(30) Foreign Application Priority Data
Sep. 11, 2014 (KR) 10-2014-0119844
Dec. 29, 2014 (KR) 10-2014-0192273

(51) Int. Cl. H01L 51/52; H01L 51/56

(52) U.S. Cl. CPC H01L 51/5268; H01L 51/56; H01L 51/5203; H01L 51/5275; H01L 2251/5338

(57) ABSTRACT

The present invention relates to a light extraction substrate for an organic light-emitting diode, a manufacturing method therefor, and an organic light-emitting diode including the same and, more specifically, to: a light extraction substrate for an organic light-emitting diode, which can improve light extraction efficiency of an organic light-emitting diode by reducing a distance between an organic light-emitting layer and a light extraction layer of the organic light-emitting diode more than a conventional distance therebetween; a manufacturing method therefor; and an organic light-emitting diode including the same. To this end, the present invention provides a light extraction substrate for an organic light-emitting diode, a manufacturing method therefor, and an organic light-emitting diode including the same, the light extraction substrate comprising: a base substrate; a mesh net-type metal material formed on the base substrate; matrix layers formed on the base substrate, wherein the matrix layers are respectively formed in a plurality of spaces partitioned by the mesh net-type metal material; and a plurality of light scatterers dispersed inside the matrix layers.

### TECHNICAL FIELD

The present disclosure relates to a light extraction substrate for an organic light-emitting diode (OLED) device, a method of manufacturing the same, and an OLED device including the same. More particularly, the present disclosure relates to a light extraction substrate for an OLED device, a method of manufacturing the same, and an OLED device including the same, in which the distance between an organic light-emitting layer and a light extraction layer of the OLED device can be reduced to be smaller than those of conventional OLED devices to improve the light extraction efficiency of the OLED device.

### BACKGROUND ART

Generally, an organic light-emitting diode (OLED) is comprised of an anode, a light-emitting layer, and a cathode. Here, when a voltage is induced between the anode and the cathode, holes from the anode are injected into a hole injection layer, from which holes migrate to an emission layer through a hole transport layer, while electrons from the cathode are injected into an electron injection layer, from which electrons migrate to the emission layer through an electron transport layer. The electrons and the holes that have migrated into the emission layer recombine with each other, thereby generating excitons. When these excitons transit from an excited state to a ground state, light is emitted.

Organic light-emitting display devices including such OLEDs are divided into passive matrix organic light-emitting display devices and active matrix organic light-emitting display devices, according to the driving modes of N×M number of pixels arranged in a matrix pattern utilized thereby.

In the case of active matrix organic light-emitting display devices, a pixel electrode defining an emission region and a unit pixel driving circuit for applying an electric current or a voltage to the pixel electrode are disposed in a unit pixel area. The unit pixel driving circuit includes at least two thin-film transistors (TFTs) and a single capacitor to enable the supply of a certain amount of electric current, irrespective of the number of pixels, thereby obtaining a reliable level of luminance. Such active matrix organic light-emitting display devices may be adaptable to high resolution and large displays, due to having reduced power consumption.

However, in the case of an OLED-based lighting device having a planar light source, at least half of light generated by the light-emitting layer is lost by reflection or absorption inside of or at the boundaries of the diode, due to the thin film multilayer structure, instead of exiting forwards. Thus, an additional amount of current must be applied to obtain a desired level of luminance. In this case, however, power consumption may increase, thereby reducing the lifetime of the diode.

To overcome this problem, a technology for forwardly extracting light that would otherwise be lost in the interior or at the boundaries of an OLED is required. This technology is referred to as light extraction technology. A problem solving scheme, based on light extraction technology, is intended to remove any factor preventing light from traveling forwards, so that that the light is not lost inside of or at the boundaries of the OLED, or to obstruct the travel of light. In this regard, external light extraction methods and internal light extraction methods are typically used. External light extraction methods are devised to reduce total internal reflection at the boundary between a substrate and surrounding air by forming textures in the surface of the outermost portion of the substrate or coating the outermost portion with a layer having a different refractive index from the substrate. Internal light extraction methods are devised to reduce a waveguide effect in which light travels along the boundary between layers having different refractive indices and thicknesses instead of traveling forwards through the boundary, by forming surface textures between a substrate and a transparent electrode or forming a coating layer having a different refractive index from the substrate between a substrate and a transparent electrode.

Regarding conventional light extraction substrates for an OLED device, an internal light extraction layer is disposed on a glass substrate, and an electrode acting as an anode of an OLED is disposed on top of the internal light extraction layer. However, the thickness of the layered electrode may increase the distance between an organic light-emitting layer and the internal light extraction layer of the OLED, thereby functioning to reduce the light extraction efficiency of the OLED device.

### RELATED ART DOCUMENT

Korean Patent No. 10-0338332 (May 15, 2002)

### DISCLOSURE

### Technical Problem

Accordingly, the present disclosure has been made in consideration of the above problems occurring in the related art, and the present disclosure proposes a light extraction substrate for an organic light-emitting diode (OLED) device, a method of manufacturing the same, and an OLED device including the same, in which the distance between an organic light-emitting layer and a light extraction layer of the OLED device can be reduced to be smaller than those of conventional OLED devices to improve the light extraction efficiency of the OLED device.

### Technical Solution

According to an aspect of the present disclosure, a light extraction substrate for an OLED device may include: a base substrate; a metal mesh disposed on the base substrate; a matrix layer disposed on the base substrate to fill a plurality of openings in the metal mesh, respectively; and a number of light scatterers dispersed in the matrix layer.

The top surface of the metal mesh may be flush with the top surface of the matrix layer.

The matrix layer may be formed from a material, the material having a refractive index higher than a refractive index of the number of light scatterers.

The matrix layer may be formed from one or a combination of at least two selected from a candidate group of metal oxides, consisting of SiO₂, TiO₂, ZrOₓ, ZnO, and SnO₂.

The matrix layer may be formed from rutile TiO₂.

The matrix layer may contain a number of voids having irregular shapes therein.

The sizes of the number of voids may range from 50 nm to 900 nm.

The number of light scatterers may be particles, voids, or a combination thereof.

In this case, each of the particles may have a single refractive index or multiple refractive indices.

The particles may be a combination of single refractive particles having a single refractive index and multiple refractive particles having multiple refractive indices.

Each of the multiple refractive particles may include a core and a shell surrounding the core, the shell having a different refractive index from the core.

The core may be hollow.

The metal mesh may be used as an electrode of an OLED.

The base substrate may be a flexible substrate.

The base substrate may be a thin glass sheet having a thickness of 1.5 mm or less.

According to another aspect of the present disclosure, an OLED device may include the above-described light extraction substrate in a portion thereof, through which light generated thereby exits.

According to further another aspect of the present disclosure, provided is a method of manufacturing a light extraction substrate for an OLED device. The method may include: forming a metal mesh on a base substrate; forming a light extraction layer on the base substrate on which the metal mesh is formed, the light extraction layer including a matrix layer and a number of light scatterers dispersed within the matrix layer; and polishing the light extraction layer so that a top surface of the metal mesh is exposed externally.

The metal mesh may be formed by one selected from the group consisting of deposition, printing, and photolithography.

The light extraction layer may be formed by coating the base substrate with a mixture prepared by mixing a material of the matrix layer with the number of light scatterers having a particle shape.

In the step of forming the light extraction layer, the mixture may be mixed with thermally curable polymer particles.

The light extraction layer may be formed by depositing the number of light scatterers having a particle shape on the base substrate and then depositing a material of the matrix layer on the base substrate such that the resultant matrix layer covers the number of light scatterers and the metal mesh.

In the step of forming the light extraction layer, the material of the matrix layer may be mixed with thermally curable polymer particles.

In the step of forming the light extraction layer, the material of the matrix layer includes a material, the material having a refractive index higher than a refractive index of the number of light scatterers.

### Advantageous Effects

According to the present disclosure, a metal mesh able to act as an electrode of an OLED device is disposed within a light extraction layer, such that the distance between the light extraction layer and an organic light-emitting layer of the OLED device can be reduced to be shorter than the distance between a light extraction layer and an organic light-emitting layer of a conventional OLED device having a multilayer structure in which the light extraction layer and an OLED electrode form different layers. This can consequently reduce the amount of light lost before striking the light extraction layer after being generated by the organic light-emitting layer, thereby improving the light extraction efficiency of the OLED device.

In addition, according to the present disclosure, the metal mesh forms regular barriers within the light extraction layer. The regular barriers can extract more light by preventing light from being waveguided within the light extraction layer, thereby further improving light extraction efficiency.

### DESCRIPTION OF DRAWINGS

FIG. 1 is a cross-sectional view illustrating an OLED device according to an embodiment of the present disclosure, with a light extraction substrate for an OLED device disposed on one surface of an OLED, through which light generated by the OLED exits;

FIGS. 2 to 5 are process views illustrating a method of manufacturing a light extraction substrate for an OLED device according to an embodiment of the present disclosure, in the sequence of processes; and

FIG. 6 is a scanning electron microscope (SEM) image captured from a matrix layer formed from rutile crystalline TiO₂.

### MODE FOR INVENTION

Hereinafter, a light extraction substrate for an organic light-emitting diode (OLED) device, a method of manufacturing the same, and an OLED device including the same will be described in detail with reference to the accompanying drawings.

In the following description, detailed descriptions of known functions and components incorporated herein will be omitted in the case that the subject matter of the present disclosure may be rendered unclear by the inclusion thereof.

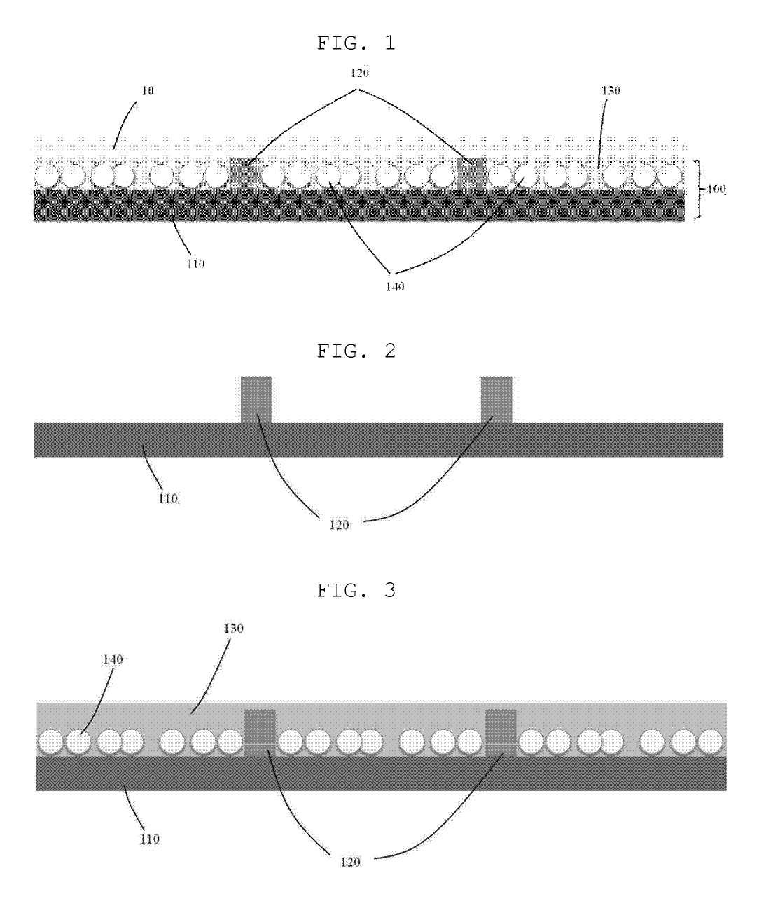

As illustrated in FIG. 1, a light extraction substrate 100 for an OLED device according to an embodiment of the present disclosure is a substrate disposed in a portion of an OLED device, through which light generated by the OLED 10 exits, to improve the light extraction efficiency of the OLED device.

Although not specifically shown, the OLED 10 has a multilayer structure sandwiched between the light extraction substrate 100 according to an embodiment of the present disclosure and another substrate facing the light extraction substrate 100. The multilayer structure is comprised of an anode, an organic light-emitting layer, and a cathode. According to an embodiment of the present disclosure, a metal mesh 120 (to be described later) internally provided in a light extraction layer can act as an anode, and an anode of a typical multilayer structure may be omitted. This will be described in more detail later. The anode may be formed from, for example, a metal, such as Au, In, Sn, or a metal oxide, such as indium tin oxide (ITO), having a greater work function to facilitate hole injection. The cathode may be a metal thin film formed from Al, Al:Li or Mg:Ag that has a smaller work function to facilitate electron injection. When the OLED 10 has a top emission structure, the cathode may have a multilayer structure including a semitransparent electrode of a thin film formed from a metal, such as Al, Al:Li, or Mg:Ag, and a transparent electrode of a thin film formed from an oxide, such as ITO, to facilitate the transmission of light generated by the organic light-emitting layer. In addition, the organic light-emitting layer may include a hole injection layer, a hole transport layer, an emission layer, an electron transport layer, and an electron injection layer that are sequentially stacked on the anode. When the OLED 10 according to an embodiment of the present disclosure is a white OLED used for lighting, the light-emitting layer may have, for example, a multilayer structure comprised of a high-molecular light-emitting layer that emits blue light and a low-molecular light-emitting layer that emits orange-red light, or a variety of other structures that emit white light may be used. The OLED 10 may also have a tandem structure. In this case, a plurality of organic light-emitting layers may alternate with interconnecting layers.

According to the above-described structure, when a forward voltage is induced between the anode and the cathode, electrons migrate from the cathode to the emission layer through the electron injection layer and the electron transport layer, while holes migrate from the anode to the emission layer through the hole injection layer and the hole transport layer. The electrons and the holes that have migrated into the emission layer recombine with each other, thereby generating excitons. When these excitons transit from an excited state to a ground state, light is generated. The brightness of the generated light is proportional to the amount of current flowing between the anode and the cathode.

The light extraction substrate 100 employed to improve the light extraction efficiency of the OLED device includes a base substrate 110, a metal mesh 120, a matrix layer 130, and a number of light scatterers 140.

The base substrate 110 is a substrate supporting the metal material 120 and the matrix layer 130 disposed on one surface thereof. In addition, the base substrate 110 is disposed in the front portion of the OLED device, i.e. on one surface of the OLED 10, through which light generated by the OLED 10 exits, to allow generated light to pass therethrough while acting as an encapsulation substrate protecting the OLED 10 from the external environment.

The base substrate 110 may be any transparent substrate that has superior light transmittance and mechanical properties. For example, base substrate 110 may be formed from a polymeric material, such as a thermally or ultraviolet (UV) curable organic film. Alternatively, the base substrate 110 may be formed from chemically strengthened glass, such as soda-lime glass (SiO₂—CaO—Na₂O) or aluminosilicate glass (SiO₂—Al₂O₃—Na₂O). When the OLED device including the light extraction substrate 100 according to an embodiment of the present disclosure is used for lighting, the base substrate 110 may be formed from soda-lime glass. The base substrate 110 may also be a metal oxide substrate or a metal nitride substrate. Alternatively, the base substrate 110 may be a flexible substrate, more particularly, a thin glass sheet having a thickness of 1.5 mm or less. The thin glass sheet may be manufactured using a fusion process or a floating process.

The metal mesh 120 is disposed on the base substrate 110. Thus, a plurality of openings are formed in the metal mesh 120 disposed on the base substrate 110. The plurality of openings have the metal mesh 120 as their walls and exposed surface portions of the base substrate 110 as their bottoms. The plurality of openings are filled by the matrix layer 130 and the number of light scatterers 140.

According to an embodiment of the present disclosure, the top surface of the metal mesh 120 (in the drawings) is flush with the top surface of the matrix layer 130 filling or located in the plurality of openings. The metal mesh 120 may act as an electrode, for example, an anode, of the OLED 10. Specifically, the organic light-emitting layer of the OLED 10 is disposed on the planar surface including the top surface of the metal mesh 120 and the top surface of the matrix layer 130, and the metal mesh 120 is electrically connected to the organic light-emitting layer to act as the anode of the OLED 10.

As described above, exemplary embodiments provide a horizontal structure of the electrode and the light extraction layer, in which the electrode of the OLED 10 formed of the metal mesh 120 and the light extraction layer formed of the matrix layer 130 containing the number of light scatterers 140 are arranged horizontally. This means the distance between the organic light-emitting layer and the light extraction layer in the OLED 10 is shorter than the distance between the organic light-emitting layer and the light extraction layer in a conventional multilayer or vertical structure in which the anode and the light extraction layer are stacked on each other. When the distance that light generated by the organic light-emitting layer travels before striking the light extraction layer is reduced, light loss is reduced by an amount corresponding to the reduced distance. This can consequently improve the light extraction efficiency of the OLED 10.

When the metal mesh 120 and the matrix layer 130 divided into a plurality of areas are regarded as a single light extraction layer, the metal mesh 120 forms regular barriers within the light extraction layer. The regular barriers can extract more light by preventing light from being waveguided within the light extraction layer, thereby further improving light extraction efficiency.

The matrix layer 130 is disposed within the plurality of openings, with the walls thereof being formed of the metal material 120 and the bottoms thereof being formed of the exposed surface portions of the base substrate 110. In addition, the number of light scatterers 140 are dispersed in the matrix layer 130.

When the light extraction substrate 100 according to an embodiment of the present disclosure is used as the internal light extraction substrate of the OLED 10, the matrix layer 130 work in concert with the number of light scatterers 140 to act as the internal light extraction layer of the OLED 10. According to an embodiment of the present disclosure, the metal mesh 120 being flush with the top surface of the matrix layer 130 while dividing the matrix layer 130 acts as the anode of the OLED 10, such that the matrix layer 130 is vertically in contact with the organic light-emitting layer of the OLED 10. In addition, the matrix layer 130 may be formed from a high refractive index (HRI) material, the refractive index of which is higher than the refractive index of the number of light scatterers 140, to form the light extraction layer. For example, the matrix layer 130 may be formed from one or a combination of at least two selected from a candidate group of metal oxides, consisting of SiO₂, TiO₂, ZrOₓ, ZnO, and SnO₂. When the number of light scatterers 140 are formed from SiO₂, the matrix layer 130 may be formed from ZnO, the refractive index of which is higher than the refractive index of SiO₂. When the matrix layer 130 is formed from rutile TiO₂ as illustrated in a scanning electron microscope (SEM) image of FIG. 6, a number of irregularly-shaped voids having sizes ranging from about 50 nm to about 900 nm are formed in TiO₂ in the process of firing TiO₂ to form the matrix layer 130. The number of voids provide a complicated scattering structure together with the number of light scatterers 140, thereby improving the light extraction efficiency of the OLED 10. The number of voids can realize a light scattering effect equal to or higher than the light scattering effect of the number of light scatterers 140. The more the voids having irregular shapes are formed within the matrix layer 130 formed from rutile TiO₂, i.e. the greater the area occupied by the number of voids in the matrix layer 130 is, the greater the degree of light extraction efficiency is. As described above, the increased number of voids formed within the matrix layer can decrease the amount of the number of light scatterers 140 that are relatively expensive, thereby reducing manufacturing costs.

The number of light scatterers 140 are dispersed within the matrix layer 130. The number of light scatterers 140 according to an embodiment of the present disclosure may be a number of particles or voids, or may be a combination of particles and voids that are combined in a predetermined ratio.

The number of light scatterers 140 in the form of particles (hereinafter, also referred to as the number of light-scattering particles 140) may be formed of a material, the refractive index of which is lower than the refractive index of the matrix layer 130.

According to an embodiment of the present disclosure, the number of light-scattering particles 140 form the light extraction layer together with the matrix layer 130. That is, the number of light scatterers 140 not only have a different refractive index from the matrix layer 130, but also diversify the paths of light generated by the OLED 10, thereby improving the light extraction efficiency of the OLED device.

Each of the number of light-scattering particles 140 may have multiple refractive indices. For example, each of the number of light-scattering particles 140 may have a core-shell structure of a core and a shell that provide different refractive indices. In the core-shell structure, the core may be hollow. When the number of light-scattering particles 140 respectively have the core-shell structure, the different refractive indices of the core and the shell can further improve the light extraction efficiency of the OLED device.

In a case in which all of the number of light scatterers 140 are light-scattering particles, the entirety of the number of light scatterers 140 dispersed within the matrix layer 130 may be particles having a core-shell structure or particles having a single refractive index. Alternatively, the number of light scatterers 140 may be a mixture of multiple refractive particles, such as core-shell particles, respectively having multiple refractive indices and single refractive particles respectively having a single refractive index.

As described above, in the light extraction substrate 100 for an OLED device according to an embodiment of the present disclosure, the metal mesh 120 acting as the anode of the OLED 10 is provided in the light extraction layer comprised of the matrix layer 130 and the number of light scatterers 140. Thus, it is possible to reduce the thickness of an OLED device by an amount equal to the thickness of an anode that is layered on a light extraction layer in a conventional OLED device, whereby the distance that light generated by the organic light-emitting layer travels before striking the light extraction layer can be reduced by an amount equal to the thickness of the anode. This can consequently improve the light extraction efficiency of the OLED device.

Hereinafter, a method of manufacturing a light extraction substrate for an OLED device according to an embodiment of the present disclosure will be described with reference to FIGS. 2 to 5.

The method of manufacturing a light extraction substrate for an OLED device according to an embodiment of the present disclosure includes a metal material forming step, a light extraction layer forming step, and a light extraction layer polishing step.

First, as illustrated in FIG. 2, in the metal material forming step, a metal mesh 120 is formed on a base substrate 110. In the metal material forming step, the metal mesh 120 may be formed on the base substrate 110 by a range of methods. For example, in the metal material forming step, the metal mesh 120 may be formed by a process selected from among deposition, printing, and photolithography.

Subsequently, as illustrated in FIG. 3, in the light extraction layer forming step, a light extraction layer is formed on the base substrate 110 on which the metal mesh 120 is formed. When the metal mesh 120 is formed on the base substrate 110 in the metal material forming step, surface portions of the base substrate 110 are exposed externally as having a grid pattern, and a plurality of openings having the exposed surface portions as their bottoms and the metal mesh 120 as their walls are formed. In the light extraction layer forming step, a matrix layer 130 having a number of light scatterers 140 dispersed therewithin is formed to fill the plurality of openings and cover the entire top surface of the metal mesh 120. In the light extraction layer forming step, the light extraction layer, i.e. the matrix layer 130 and the number of light scatterers 140, may be formed by a range of methods. For example, the light extraction layer forming step may include preparing a mixture by mixing a material of the matrix layer 130 with a number of light-scattering particles 140 and then coating the base substrate 110 with the prepared mixture, such that the mixture entirely covers the metal mesh 120. After the base substrate 110 is coated with the mixture, the mixture may be dried and then fired. In the light extraction layer forming step, the mixture may be additionally mixed with thermally curable polymer particles to form a number of light scatterers 140 in the form of voids (hereinafter, also referred to as the number of light-scattering voids 140). The thermally curable polymer particles mixed in this manner are evaporated during the firing process for making the matrix layer 130 from the mixture, and the number of light-scattering voids 140 are formed in sites that the thermally curable polymer particles occupied before being evaporated.

In another example, the light extraction layer forming step may include depositing a number of light-scattering particles 140 on the base substrate 110 and then depositing a material of the matrix layer 130 on the base substrate 110, such that the resultant matrix layer 130 covers the number of light scatterers 140 and the metal mesh 120. In this case, the material of the matrix layer 130 may be mixed with thermally curable polymer particles to form a number of light-scattering voids 140.

In the light extraction layer forming step, the number of light-scattering particles 140 may respectively have a single refractive index. Alternatively, the number of light-scattering particles 140 may respectively have multiple refractive indices. For example, the number of light-scattering particles 140 may respectively have a core-shell structure, in which the core is hollow. In addition, a mixture in which single refractive light-scattering particles and multiple refractive light-scattering particles are mixed in a predetermined ratio may be used.

In the light extraction layer forming step, the matrix layer 130 may be formed from a material, the refractive index of which is greater than the refractive index of the number of light scatterers 140. For example, in the light extraction layer forming step, the material of the matrix layer 130 may be one or a combination of at least two selected from a candidate group of metal oxides, consisting of SiO₂, TiO₂, ZrOₓ, ZnO, and SnO₂. When the matrix layer 130 is formed from ZnO, the number of light scatterers 140 may be formed from SiO₂, the refractive index of which is smaller than the refractive index of ZnO. In addition, when the matrix layer 130 is formed from rutile TiO₂, a number of irregularly-shaped voids having sizes ranging from 50 nm to 900 nm may be formed within the matrix layer 130 in the process of firing rutile TiO₂.

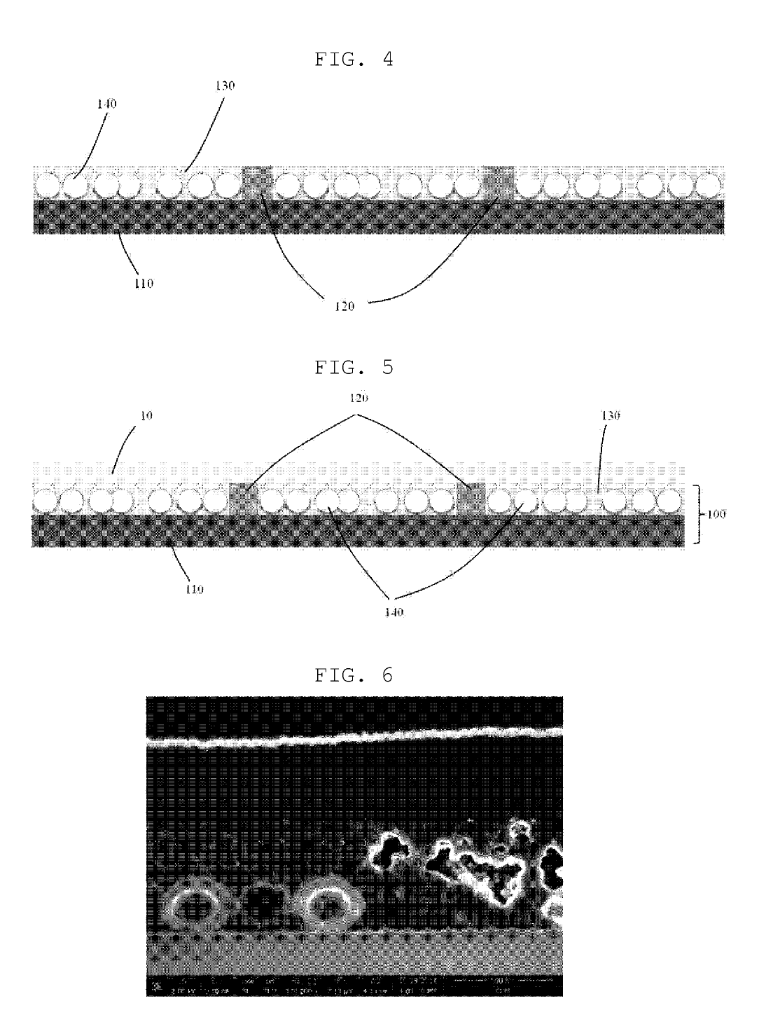

Afterwards, as illustrated in FIG. 4, in the light extraction layer polishing step, the light extraction layer, more particularly, the matrix layer 130, is polished, so that the top surface of the metal mesh 120 is exposed externally. When the matrix layer 130 is polished, the manufacturing of a light extraction substrate 100 is completed. Here, the surface of the light extraction substrate 100 in contact with an OLED 10 (FIG. 5) is a high flat surface.

In addition, when the top surface of the metal mesh 120 is exposed by the light extraction layer polishing step, the metal mesh 120 can be electrically connected to the OLED 10, as illustrated in FIG. 5. Thus, the metal mesh 120 functions as an electrode acting as the anode of the OLED 10.

The foregoing descriptions of specific exemplary embodiments of the present disclosure have been presented with respect to the drawings. They are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

1. A light extraction substrate for an organic light-emitting diode device, the light extraction substrate comprising:
a base substrate;
a metal mesh disposed on the base substrate;
a matrix layer disposed on the base substrate to fill a plurality of openings in the metal mesh, respectively; and
a number of light scatterers dispersed in the matrix layer.

2. The light extraction substrate of claim 1, wherein a top surface of the metal mesh is flush with a top surface of the matrix layer.

3. The light extraction substrate of claim 1, wherein the matrix layer is formed from a material, the material having a refractive index higher than a refractive index of the number of light scatterers.

4. The light extraction substrate of claim 3, wherein the matrix layer is formed from one or a combination of at least two selected from a candidate group of metal oxides, consisting of SiO₂, TiO₂, ZrOₓ, ZnO, and SnO₂.

5. The light extraction substrate of claim 4, wherein the matrix layer is formed from rutile TiO₂.

6. The light extraction substrate of claim 5, wherein the matrix layer contains a number of voids having irregular shapes therein.

7. The light extraction substrate of claim 6, wherein sizes of the number of voids range from 50 nm to 900 nm.

8. The light extraction substrate of claim 1, wherein the number of light scatterers comprise particles, voids, or a combination thereof.

9. The light extraction substrate of claim 8, wherein each of the particles has a single refractive index or multiple refractive indices.

10. The light extraction substrate of claim 9, wherein the particles comprise a combination of single refractive particles having a single refractive index and multiple refractive particles having multiple refractive indices.

11-12. (canceled)

13. The light extraction substrate of claim 1, wherein the metal mesh is used as an electrode of an organic light-emitting diode.

14. The light extraction substrate of claim 1, wherein the base substrate comprises a flexible substrate.

15. (canceled)

16. An organic light-emitting diode device comprising the light extraction substrate as claimed in claim 1 in a portion thereof, through which light generated thereby exits.

17. A method of manufacturing a light extraction substrate for an organic light-emitting diode device, the method comprising:
forming a metal mesh on a base substrate;
forming a light extraction layer on the base substrate on which the metal mesh is formed, the light extraction layer comprising a matrix layer and a number of light scatterers dispersed within the matrix layer; and
polishing the light extraction layer so that a top surface of the metal mesh is exposed externally.

18. The method of claim 17, wherein the metal mesh is formed by one selected from the group consisting of deposition, printing, and photolithography.

19. The method of claim 17, wherein the light extraction layer is formed by coating the base substrate with a mixture prepared by mixing a material of the matrix layer with the number of light scatterers having a particle shape.

20. The method of claim 19, wherein, in forming the light extraction layer, the mixture is mixed with thermally curable polymer particles.

21. The method of claim 17, wherein the light extraction layer is formed by depositing the number of light scatterers having a particle shape on the base substrate and then depositing a material of the matrix layer on the base substrate such that the resultant matrix layer covers the number of light scatterers and the metal mesh.

22. The method of claim 21, wherein, in forming the light extraction layer, the material of the matrix layer is mixed with thermally curable polymer particles.

23. The method of claim 17, wherein, in forming the light extraction layer, the material of the matrix layer comprises a material, the material having a refractive index higher than a refractive index of the number of light scatterers.
